(19) United States
(12) Patent Application Publication
(10) Pub. No.: US 2025/0290741 A1
(43) Pub. Date: Sep. 18, 2025

(54) Sensor device for a Position Sensor and Sensor System with such a Sensor device

(71) Applicant: SUMIDA Components & Modules GmbH, Obernzell (DE)

(72) Inventors: Markus SIMON, Hutthurm (DE); Philipp KROHN, Neuburg am Inn (DE)

(21) Appl. No.: 19/065,528

(22) Filed: Feb. 27, 2025

(30) Foreign Application Priority Data
Mar. 18, 2024 (DE) 102024107561.9

(51) Int. Cl. G01B 7/30; H05K 1/11; H05K 1/14

(52) U.S. Cl. CPC G01B 7/30; H05K 1/115; H05K 1/14; H05K 2201/10015; H05K 2201/10022; H05K 2201/10151

(57) ABSTRACT

A sensor device for a position sensor, preferably a rotor position sensor, with a printed circuit board is provided. The sensor device includes a primary winding and at least one secondary winding, and a device body. At least one of the primary winding and the at least one secondary winding is formed at least partially by a bendable conductor wire. One of the bendable conductor wire of the primary winding and the at least one secondary winding is mounted completely on a surface portion of the device body.

### FIELD OF THE INVENTION

The present invention relates to a sensor device for a position sensor, preferably a rotor position sensor, and a sensor system with such a sensor device. In particular, the present invention relates to a sensor device that is used in a position sensor in order to detect, together with a target element that is arranged rotatably relative to the sensor device, an angular position of the target element relative to the sensor device.

### RELATED ART

In many technical fields, it is necessary to determine the position of a moving object with a degree of accuracy that is predetermined by the respective application. To this end, numerous sensor systems have been developed in which at least the relative position between two elements may be measured with sufficient precision by means of, for example, optical, electrical, magnetic and other interactions. Particularly, sensor arrangements are often used in technical areas in which very demanding environmental conditions prevail, such as high operating temperatures in conjunction with high magnetic fields, which may be caused, for example, by high operating currents, wherein the position-dependent generation of eddy currents is used in such sensor arrangements to determine the position of a component. For this purpose and in some examples of such an eddy current sensor arrangement, the damping of one or more coils caused by eddy currents is detected, wherein the one or more coils are provided as stationary components and a moving component has a track made of a suitable material, which leads to a position-dependent generation of eddy currents and thus damping. On the basis of this position-dependent generation of eddy currents, the position of the moving track with respect to the one or more stationary coils may be determined by correlating the attenuation caused and the particular shape of the track.

An illustrative example of such an application is determining the position of a rotor of an electrical machine in order to determine suitable control signals for supplying suitable current and voltage values. For example, in many cases where highly variable speeds and a moderately wide control bandwidth are required for the electrical machine, it is important to acquire output voltage signals from sensor systems with a high temporal resolution in order to determine the position of the rotor with relative precision. In order to operate permanent magnet synchronous machines efficiently, for example, it is necessary to know the position of the rotor within an angular segment with a high degree of accuracy, corresponding to the number of poles, in order to supply the stator windings with a suitable current to achieve a desired mode of operation. Non-contact sensor arrangements based on coils are often used for this purpose. However, these require a relatively large space for the coils and the associated evaluation electronics. Frequently, a very close spatial coupling between the target element and the rotor is required in the electrical machine, whereby high currents with correspondingly high magnetic fields, as well as relatively high temperatures, occur in the vicinity of the target element, which may lead to interference in the output signals of the coils. This susceptibility ultimately also results in a poorer spatial resolution of the position of a rotor. In addition to a desired interference immunity with regard to high magnetic fields, an adaptation of the sensor arrangement to operating conditions of the electrical machine is also desired with regard to the sensor arrangement, for example with regard to the prevailing temperatures, the required speed range, and the like.

In addition to the above aspects, and independently of a specific application, the provision and integration of components of a sensor system requires a high degree of consistent precision in the production of sensor arrays, for example in mass production. This allows for a consistent functioning of sensor arrays without the need for extensive adjustment work when installing them in the end application.

Commercially available evaluation circuits generally use a large-area primary winding that encloses at least two sinusoidal secondary coils. When operating a rotor position encoder with such an evaluation circuit, a rectangular encoder element changes the coupling between the primary winding and the secondary coils, which are realized as planar coils in printed circuit board technology. Conventional evaluation circuits for rotor position sensors provide a circular printed circuit board in multilayer technology with four layers, with the planar coils for primary and secondary coils usually being formed on two of the four layers, while further layers are provided for an integrated circuit of the evaluation circuit.

Document DE 10 2016 202 877 B3 shows a rotation angle sensor with a stator element that has a transmitting coil and at least two receiving coils arranged within the transmitting coil, which are arranged on a printed circuit board, and a rotor element that is mounted so that it can rotate about an axis of rotation with respect to the stator element, via which the transmitting coil is inductively coupled to the at least two receiving coils, so that the inductive coupling is dependent on a rotation angle between the stator element and the rotor element and the transmitting coil induces at least two angle-dependent alternating voltages in the at least two receiving coils. The rotor element and the at least two receiving coils are designed in such a way that an alternating voltage is induced in the receiving coils, the amplitude of which is sinusoidally dependent on the angle of rotation. The at least two receiving coils are constructed from electrically connected conductor tracks in the form of circular arcs, so that each of the at least two receiving coils is constructed from partial windings oriented in opposite directions with respect to a current flow, each of which is bounded in a radial direction by at least one circular arc-shaped conductor track curved to the left and at least one opposing circular arc-shaped conductor track curved to the right.

A planar linear inductive position sensor is known from the document DE 11 2019 006 893 T5, which comprises a substrate, at least one oscillation coil, a first sensor coil having opposite edges extending over the opposite edges of the oscillation coil along a linear axis along which a linear position of a conductive object is to be detected, and a second sensor coil having opposing edges extending over opposing edges of the voice coil along the linear axis. The first sensor coil and the second sensor coil have geometries that are selected such that equal opposite magnetic fields are induced in the first and second sensor coils in the presence of a magnetic field generated by the oscillating coil when there is no conductive object to be measured in the vicinity of the first and second sensor coils, and unequal opposite magnetic fields are induced in the first and second sensor coils when the conductive measurement object is in the vicinity of the first and second sensor coils. A difference in the unequal opposite magnetic fields induced in the first and second sensor coils correlates with the position of the conductive measurement object.

Since the price of a printed circuit board is mainly based on the number of its layers and the required area, the commercially available evaluation circuits described above are high-priced.

In view of the state of the art as described above, it is desirable to provide a sensor device for a position sensor and a sensor system with such a sensor device with lower manufacturing costs compared to conventional devices and systems.

### SUMMARY

Sensor devices and sensor systems according to the invention are used to determine the position of an object moved and/or displaced relative to a reference object, such as, for example, in rotor position sensors for determining the angle of an object twisted or rotating relative to a reference object.

At least some problems of the state of the art are solved in various aspects of the present disclosure by the common inventive concept of reducing costs incurred by printed circuit boards in conventional position sensors in sensor devices according to the invention and in sensor systems with such sensor devices. A solution as presented herein in the various aspects is achieved by at least partially replacing costly printed circuit boards with inexpensive printed circuit boards or with wire windings at least partially formed of one or more bendable conductor wires provided outside a printed circuit board.

Conductor wire means a bendable or flexible conductor wire that can be temporarily wound on a cylindrical bobbin for storage and can be unwound from the bobbin when required. In contrast to a conductor track on a printed circuit board or the like, the conductor wire is a self-supporting structure, whereas the conductor track on a printed circuit board is formed as a deposited and patterned track which is not independent of the printed circuit board (i.e., the conductor track does not exist without a surface on which it is formed). In other words, the conductor wire according to the present description exists in itself and independently of whether it is attached to a printed circuit board. In this sense, “bendable conductor wire” and “self-supporting conductor wire” are to be understood as intrinsic features which designate the conductor wire as such as a conductor wire in the original sense of the word, which designates an electrically conductive wire as an independent structural feature independent of a further structure, such as a surface, a carrier, a printed circuit board, etc. In the present application, “bendable conductor wire” and “self-supporting conductor wire” may be replaceable.

In a first aspect, the present invention provides a sensor device for a position sensor, such as a rotor position sensor or, in general, a position sensor that detects not only the position of an electric machine rotor but also the position of any rotating part, such as a part that is flanged to an electric machine rotor, for example via a gearbox, or a rotating part that only rotates in a limited angular range or which rotates continuously. For example, the sensor device applied to resolvers.

In the first aspect of the invention, a sensor device is provided which is intended for a position sensor having a printed circuit board. In specific illustrative embodiments of the first aspect, the sensor device may be provided as a sensor device for rotor position sensors.

In the illustrative embodiments of the first aspect, the sensor device comprises a device body, a primary winding and at least one secondary winding, wherein at least one of the primary winding and the at least one secondary winding is at least partially formed by a conductor wire. The conductor wire of the primary winding and/or the conductor wire of the at least one secondary winding is completely attached to a surface portion of the device body, for example the conductor wire of the primary winding and/or the at least one secondary winding may be attached to the surface portion of the device body. The primary winding and/or the at least one secondary winding may, for example, be formed entirely by conductor wire, with the conductor wire of the primary winding and/or the conductor wire of the at least one secondary winding being attached entirely to the surface portion of the surface of the device body. For example, the conductor wire of the primary winding and/or the conductor wire of the at least one secondary winding may be completely attached to the surface portion of the device body.

In some illustrative examples herein, the the conductor wire of the primary winding and/or the conductor wire of the at least one secondary winding may be partially or completely attached to the surface portion of the device body by means of a gluing agent, such as a resin or epoxy resin and the like. Herein, a groove may be formed, such as the groove described below, and the wire formed winding(s) routed within the groove may be partially or completely embedded into the gluing agent.

In illustrative embodiments, the device body may be free of any electrical and/or electronic components therein. In particular, no electrical and/or electronic components may be integrated into the device body. The device body serves only as a support for the primary winding and/or secondary winding(s) and optionally for a printed circuit board for mounting on a surface of the device body.

According to the description herein, the conductor wire is a wire conductor which may be formed from a piece of wire, for example. For example, the piece of wire may be a piece of round wire or flat wire, wherein the conductor wire is completely mounted on a surface portion of a surface of the device body. In this case, the conductor wire at least partially forms a planar coil of at least one of the primary winding and the at least one secondary winding arranged on the surface portion of the device body. According to illustrative examples, the primary winding and/or secondary winding may be formed entirely from round wire or flat wire.

Accordingly, a sensor device may be provided at low manufacturing costs, wherein the device body acts as a coil body or carrier for the primary and secondary windings of the sensor device. For example, a device body provided as an injection molded body may be easily manufactured in large quantities with great accuracy or reproducibility at low manufacturing costs. An according device body may also provide a sustainable component, since it may be used in the course of a common part usage with a printed circuit board that may be used for several projects, since a printed circuit board to be used with the sensor device according to the invention is no longer limited in size and shape by its intended function of a device body for the sensor device.

In some examples herein, the device body may only carry the primary and secondary windings on its surface. The device body may be free of any integrated electric and/or electronic component integrated into the device body such that no electric and/or electronic component is present within the device body. Accordingly, interference of windings with components mounted to the device body may be reduced.

In various illustrative embodiments of the first aspect, the device body is at most partially provided as a printed circuit board of the sensor device. In special illustrative examples, the device body does not serve as a printed circuit board of the sensor device. For example, the device body may not even be provided as a printed circuit board at all and the device body may be provided separate to a printed circuit board of the sensor device, that is, the device body may be an additional element provided in addition to a printed circuit board and the windings in the sensor device. For example, the conductor wire of at least one of the primary winding and the conductor wire of the at least one secondary winding is mounted completely independent from a printed circuit board. In special illustrative examples herein, the conductor wire of the primary winding and/or the at least one secondary winding may be completely mounted on the surface portion of the surface of the device body outside any printed circuit board.

In various illustrative embodiments of the first aspect, the sensor device comprises a primary winding and at least one secondary winding, wherein at least one of the primary winding and the at least one secondary winding is formed at least in part by a conductor wire, and a device body. The conductor wire of the primary winding and/or the at least one secondary winding is completely mounted on the surface portion of the device body.

In some illustrative examples herein, the device body may be easily adapted to several pole pair numbers and the primary and/or secondary windings may be realized at least partially independently of a printed circuit board.

In some illustrative and non-limiting examples of the first aspect, a primary winding and two secondary windings may be mounted on the device body, for examples attached to the device body. Accordingly, precise positioning during operation for a position sensor with this sensor device becomes possible.

In a first embodiment of the first aspect, the conductor wire may be routed as a planar coil section. For example, the conductor wire may be routed with a sinusoidal coil path in the planar coil section. In this way, a compact sensor device with a reduced overall height may be achieved.

In a second embodiment of the first aspect, the device body may comprise a groove in which the conductor wire of at least one of the primary winding and the at least one secondary winding is completely routed. The groove may be formed at least partially in the surface portion of the device body and formed as a shallow groove therein. Herein, a shallow groove is a groove in which a depth of the groove (measured as a dimension of the groove along a direction parallel to a surface normal of the surface portion into the device body) is smaller than any dimension of the groove measured perpendicular thereto, for example at least by a factor of 5 or 10 or 20 smaller. The conductor wire routed in the groove may prevent the conductor wire from protruding noticeably from the device body, thus avoiding damage to windings during operation. Furthermore, an overall height of the sensor device may be reduced.

In some illustrative examples of the second embodiment, the groove may have a coil accommodation groove section, for example, the coil accommodation groove section possibly being formed as a ring-shaped coil groove section in the device body. The coil accommodation groove section is laterally limited by web sections in the surface of the device body. Accordingly, it may be easy to encapsulate windings installed in the coil accommodation groove section, with the web sections laterally defining the groove.

In some other illustrative examples of the second embodiment, the groove may further comprise a printed circuit board accommodation portion configured to completely accommodate a printed circuit board, wherein the groove is formed on only one surface of the device body. By providing a corresponding groove, a sensor device with a low profile may be provided when a printed circuit board is mounted on the device body.

In a third embodiment of the first aspect, the device body may be in the form of a plate-shaped or disc-shaped body and the groove may be formed in a surface of the device body that is perpendicular to a smallest dimension of the device body. Accordingly, an advantageous design of the device body may be provided in applications aimed at detecting angular position, for example for a rotor position sensor.

In a fourth embodiment of the first aspect, the sensor device may further comprise a printed circuit board mounted on the device body and connected to at least one of the primary winding and the at least one secondary winding on the device body. A printed circuit board may be selected that is independent of the intended application of the sensor device in terms of shape and size, whereby it is now possible to select a very compact printed circuit board or to configure an existing sensor device in a simple and cost-effective manner by retroactively exchanging printed circuit boards. For example, circuit boards with a minimal surface area, i.e. an area defined only by the circuit integrated on and/or into the circuit board, and with a small number of layers, or fewer than four layers, such as only two layers or only one layer, may be used.

In a fifth embodiment of the first aspect, the printed circuit board may have an area of the device body of less than 19,000 mm². In other words, the printed circuit board may cover an area section of the surface portion of the device body of less than 19,000 mm². In illustrative examples herein, the area section may be at most 18,500 mm² or at most 18,000 mm² or at most 15,000 mm² or at most 10,000 mm² or at most 5,000 mm². For example, the area section may cover at most 3,000 mm², such as at most 2,000 mm² or at most 1,500 mm² or at most 1,300 mm². For example, a very compact and thus cost-effective printed circuit board may be selected without limiting the capability of integrated circuits on the printed circuit board.

In a sixth embodiment of the first aspect, the circuit board may comprise fewer than four layers. For example, the circuit board may have at most two layers.

In a seventh embodiment of the first aspect, the printed circuit board may only comprise contacts, discrete electrical components and an integrated circuit. In this case, the contacts are connected to the electrical components by conductor tracks and the electrical components provide at least one capacitor and/or at least one resistor as one or more discrete components. The printed circuit board may be connected to the primary and secondary windings via the contacts. Furthermore, the integrated circuit may represent at least part of an integrated evaluation and/or drive circuit that is connected to the primary winding and/or the at least one secondary winding. In this case, only the components and conductor tracks with minimum length are provided on the printed circuit board, so that a very compact design of the printed circuit board is possible.

In an second aspect, a sensor device for a position sensor, preferably a rotor position sensor, is provided with a printed circuit board. In illustrative embodiments herein, the sensor device according to the second aspect comprises a primary winding and at least one secondary winding, a device body, and a printed circuit board. At least one of the primary winding and the at least one secondary winding is formed at least in part by a bendable conductor wire. The printed circuit board is mounted on, such as attached to, the device body in conjunction with the conductor wire of at least one of the primary winding and the at least one secondary winding. The conductor wire of at least one of the primary winding and the conductor wire of the at least one secondary winding is mounted completely outside the printed circuit board on a surface portion of the device body, for example, the conductor wire of the primary winding and/or the at least one secondary winding may be completely mounted on a surface portion of a surface of the device body. The bendable conductor wire is a bendable wire conductor formed of a piece of wire, for example a piece of round wire or flat wire, wherein the conductor wire is completely routed and mounted on the surface portion, e.g., an area section of the surface of the device body outside the printed circuit board. The conductor wire thereby at least partially forms a planar coil of at least one of the primary and at least one secondary windings disposed on the planar portion of the device body.

Accordingly, a sensor device may be provided at low manufacturing costs, with the device body acting as a coil former or carrier for the primary and secondary windings of the sensor device. For example, a device body may be provided as an injection-molded body such that it may be easily manufactured in large quantities with great accuracy or reproducibility at low manufacturing costs. An according device body may be a sustainable component, since it may be used in the course of a common part usage with a printed circuit board that may be used for several projects. A printed circuit board to be used with the sensor device according to the invention is no longer defined in size and shape to function as a device body of the sensor device.

In various illustrative embodiments herein, the device body is at most partially provided as a printed circuit board of the sensor device. In some special but non-limiting example herein, the device body may not be provided as a printed circuit board. Accordingly, the device body may be provided completely independently of a printed circuit board of the sensor device or exclusively as an additional element in addition to a printed circuit board and the windings in the sensor device.

In some illustrative embodiments of the second aspect, the sensor device may further comprise at least one further feature as defined in one of the embodiments of the first aspect, in particular one of the first to fifth embodiments of the first aspect.

In a third aspect, a sensor device for a position sensor, preferably a rotor position sensor, with a printed circuit board is provided. In illustrative embodiments herein, the sensor device according to the second aspect comprises at least two circuit boards electrically connected to one another. Furthermore, the sensor device according to the third aspect comprises a primary winding and at least one secondary winding, wherein at least one of the primary winding and the at least one secondary winding is at least partially integrated into at least one of the at least two circuit boards as an at least partially integrated wiring. By using multiple circuit boards, at least one of the circuit boards may be used as a relatively inexpensive circuit board for the partially integrated wiring, thereby reducing manufacturing costs for the sensor device.

In some illustrative embodiments of the third aspect, the at least two circuit boards may include a two-layer circuit board and a more than two-layer circuit board, that is, a circuit board with more than two layers. In this case, the printed circuit board with only two layers provides a relatively inexpensive printed circuit board compared to the printed circuit board with more than two layers. The printed circuit board with more than two layers may be provided as a printed circuit board in which additional integrated circuit structures may be integrated, so that the use of high-priced printed circuit boards may be reduced by the further use of a printed circuit board with only two layers. For example, the circuit board with more than two layers may also have at least part of an evaluation and drive circuit for one or more of the windings connected to it integrated into the circuit board. Additionally or alternatively, at least one winding may be completely integrated into the circuit board with only two layers.

In further illustrative embodiments of the third aspect, the sensor device may further comprise a device body, such as an injection-molded body. The at least two printed circuit boards may be attached to the device body. Alternatively or additionally, at least one of the primary winding and the at least one secondary winding may be formed at most partially by a conductor wire. Accordingly, a surface used for windings may be provided without using printed circuit boards such that manufacturing costs may be further reduced.

In a fourth aspect, a sensor system is provided. In illustrative embodiments, the sensor system comprises a sensor device according to at least one of the first to third aspects and a target element that is rotatably arranged relative to the sensor device, wherein the target element has a target pattern that is formed of an electrically conductive material. In this way, the advantages and positive effects of the sensor device according to the first and/or second and/or third aspect are transferred to the sensor system according to the fourth aspect.

In the sensor system of the fourth aspect, an angular position between the sensor device and the target element is advantageously detected when the target element is moved relative to the sensor device. For example, relative rotational movement between the target element and the sensing device, caused by rotational movement of a rotor, which in specific applications may be a rotor of an electrical machine, may generate a voltage in the secondary windings that is dependent on the instantaneous position of the target element relative to the sensing device. In other words, a magnetic field generated by the primary winding circuit is modulated by the target element and the modulated magnetic field induces a voltage signal in the secondary windings of the sensor device, which represents a signal modulated by a target pattern of the target element of the electrical signal applied to the primary winding circuit, wherein the target pattern has an angle-dependent varying shape along an orbit of the target element with respect to the sensor device. Herein, the shape of the target pattern varies depending on a varying angle between target element and secondary winding(s).

In a fifth aspect of the present disclosure, a method of fabricating a sensor device for a position sensor, preferably a rotor position sensor, having a printed circuit board is provided. In the illustrative embodiments herein, the method comprises providing a bendable conductor wire, providing a device body, providing at least one of a primary winding and at least one secondary winding, wherein at least one of the primary winding and the at least one secondary winding are formed at least in part by the bendable conductor wire on a surface of the device body, and providing a printed circuit board (6) mounted to the device body and connected with at least one of the primary winding and the at least one secondary winding.

In the sensor device according to the first aspect and/or second aspect and/or third aspect, the primary and secondary windings may be provided as air coils, which means that the primary and secondary windings are provided without a magnetizable core. In this case, external magnetic fields do not contribute to magnetization or saturation, or only to a tolerable extent, due to the absence of a magnetic core material in the coil, the obtained output signal being relatively insensitive to interference, for example from the strong magnetic fields that occur in electrical machines. Thus, eddy current losses in the target pattern, if it is at least partially constructed from an electrically/magnetically conductive material, may be used to influence the output signals of the sensor device. Accordingly, the sensor device may be resistant to interference with regard to electromagnetic influences in accordance with the first and/or second and/or third aspect.

The method according to the fifth aspect may be used to manufacture a sensor device according to any one of the first to fourth aspects, wherein embodiments from any one of the first to fourth aspects may be combined into the fifth aspect.

### BRIEF DESCRIPTION OF THE DRAWINGS

Further advantages and illustrative embodiments of the above-described aspects of the invention will be described below with reference to the accompanying figures, wherein:

FIG. 1 schematically shows a plan view of a sensor device according to some illustrative embodiments in planar views, wherein the view in FIG. 1b is a sectional view along line 1b-1b in FIG. 1a;

FIGS. 2a and 2b schematically show, in plan view, a layer of a printed circuit board according to some illustrative embodiments; and

FIG. 3 shows a schematic representation of a sensor system according to some illustrative embodiments.

### DETAILED DESCRIPTION

Various illustrative embodiments described below may relate to an application of sensor devices in rotor position sensors without being limited per se to this application, unless explicitly stated.

According to illustrative exemplary embodiments, a rotor position sensor generally comprises a sensor system for detecting an angular position between a sensor device of the sensor system and a target element of the sensor system.

For example, the target element may be a reference object moved relative to the sensor device or may be a fixed reference object with respect to a sensor device moved relative to it. The target element has a target pattern that is formed of an electrically/magnetically conductive material and changes in an angle-dependent manner during a complete rotation (i.e. a rotation of 360° around an axis of rotation of the target element relative to the sensor device), whereby an angular position between the sensor device and the target element is detected.

In rotor position sensors with a passive target element, the sensor device has a primary winding circuit that generates a magnetic field that is modulated by the target pattern of the target element. A correspondingly modulated magnetic field in turn induces correspondingly modulated electrical signals in at least one secondary winding of the sensor device. From a comparison between an electrical signal applied to the primary winding circuit for generating the magnetic field and the electrical signal output by the at least one secondary winding in response thereto, it is possible to determine an angular position between the target element and the sensor device.

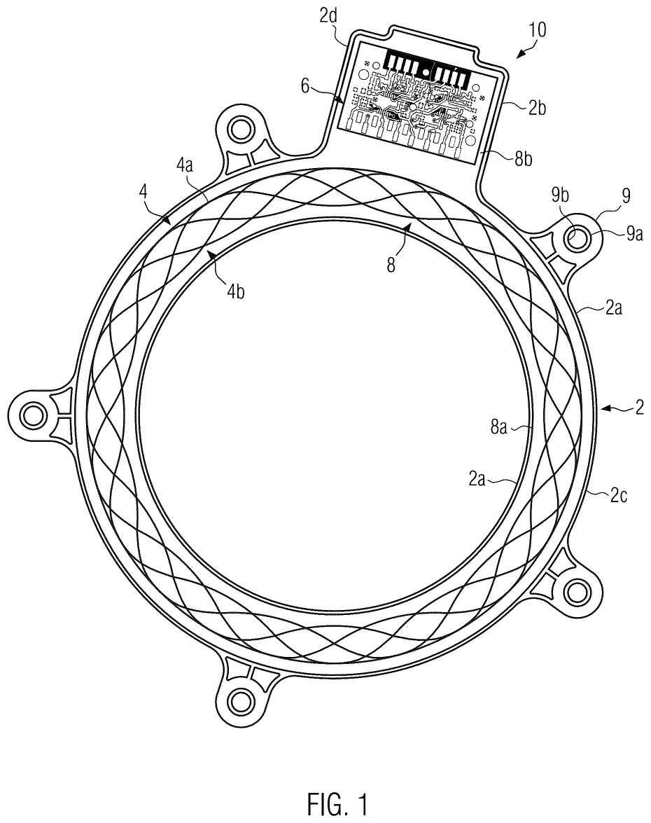

With reference to FIG. 1, a sensor device 10 for a rotor position sensor according to an illustrative embodiment of the invention for detecting an angular position between the sensor device 10 in a sensor system (not shown) and a target element (not shown) of the sensor system (not shown), is described.

FIG. 1 schematically shows, in a plan view, the sensor device 10 with a device body 2 and a coil structure 4 attached to the device body 2. The coil structure 4 may comprise, in accordance with the illustrated embodiment, a primary winding 4a and at least one secondary winding 4b (approximately two secondary windings in the embodiment illustrated in FIG. 1, although more than two secondary windings may also be provided, such as four secondary windings or more secondary windings).

In illustrative examples of the embodiment shown in FIG. 1, the device body 2 may be provided as a carrier body that is easy and inexpensive to manufacture, in particular as a body suitable for usage as a coil carrier body. For example, the device body 2 may be provided as an injection-molded body, wherein this device body 2 may be manufactured easily and reproducibly. As particularly illustrative, but non-limiting examples of possible materials for producing the device body 2, thermoplastics may be included, which may be supplemented by additives and fillers for an injection molding process and a later specific use of the device body 2 in a specific application, for example, without limitation, in an application as a device body for a position sensor in vehicle construction.

For example, materials for producing the device body 2 may be, without limitation, at least one of polyolefins, polypropylene, Plexiglas (PMMA), polycarbonate (PC), polystyrene (PS), copolymers of PS (ABS=acrylonitrile-butadiene-styrene), polyamide (PA), polyoxymethylene (POM) and many other technical plastics.

With reference to the illustration in FIG. 1, the device body 2 is formed by a coil carrier body section 2a and an optional printed circuit board carrier section 2b, wherein the optional printed circuit board carrier section 2b may be integrally formed with the coil carrier body section 2a and may be designed to carry an optional printed circuit board 6. For example, the coil carrier body section 2a may have a shape that is based on or determined by a shape and form of the coil structure 4. With reference to FIG. 1, the coil carrier body section 2a is formed as an annular device body section. However, this is not a limitation and, depending on an application in a linear position sensor, the coil support section 2a may have a linear or elongated device body section instead of an annular device body section, without affecting the following description. In particular, the preceding and following description of further structural and functional features of the sensor device 10 in FIG. 1 does not depend on a particular design of the device body section 2a, unless explicitly stated.

In some special illustrative examples and as shown in FIG. 1, the device body 2 may be designed as a plate-shaped or disc-shaped body. In particular, the coil carrier body section 2a may be designed as a disc-shaped body. The terms “disc-shaped” and “plate-shaped” are to be understood to mean that a smallest dimension of the body is oriented normal to a surface on which the coil structure 4 is arranged. Alternatively, the device body may be a linear strip shapes body (not illustrated).

With ongoing reference to FIG. 1, the circuit board carrier section 2b is oriented transversely to an extending direction of the coil structure 4 and extends transversely to the extending direction of the coil structure 4 away from the device body section 2a. The direction of extension of the coil structure 4 is defined as a direction along which a bendable conductor wire of the coil structure 4 mainly extends between connections, the term “mainly” being understood as a proportion of more than 50%, measured from a total length, in particular more than 70%. The printed circuit board carrier section 2b is of a size sufficient to hold the printed circuit board 6, so that the printed circuit board 6 may be mounted (is mountable) on the device body 2 by means of the printed circuit board carrier section 2b. The term “mountable” is understood to mean permanently or detachably attached.

In illustrative examples, as shown in FIG. 1, the primary winding 4a and the secondary windings 4b may each be formed by a bendable conductor wire that is completely mounted on a surface portion of a surface of the device body 2. The bendable conductor wire of each winding 4a, 4b in the coil structure 4 may be routed as a planar coil section, preferably with a sinusoidal coil routing in the planar coil section for the secondary windings 4b, as shown in FIG. 1, while the bendable conductor wire of the primary winding 4a is routed in a circular shape so that the secondary windings are completely enclosed within the primary winding 4a in the surface.

As shown in FIG. 1, in some exemplary embodiments, the sensor device 10 may comprise a groove 8 formed in the surface portion of the surface of the device body 2. The groove 8 is formed as a recess in the connector body 2, which is formed in the coil carrier body section 2a corresponding to a routing of the coil structure 4 as a coil accommodation groove section 8a following the routing of the coil structure 4, for receiving the coil structure 4 in the coil carrier body section 2a, so that the coil structure 4 is accommodated and embedded into the coil accommodation groove section 8a into the areas section of the surface of the device body 2. The surface portion of the surface of the device body 2 is oriented substantially perpendicular to a plane that is substantially defined by the coil structure 4. In other words, a virtual plane is defined by the coil structure 4 in that the coil structure 4 is essentially routed in a plane, which may, for example, coincide with the surface of the device body 2 on which the coil structure 4 is arranged. The coil structure 4 may be routed completely within the groove 8.

In the illustrated example of the ring-shaped coil carrier body section 2a, the coil accommodation groove section 8a is formed as a ring-shaped groove in the device body 2, which is laterally limited by web sections 2c1 and 2c2. In general, at least one web section may be provided corresponding to at least one of the web sections 2c1 and 2c2, in order to define the groove 8 in the surface of the coil carrier body section 2a on at least one side. However, this is not a restriction, since in the case of a linear position sensor, a linear coil carrier section may be formed, including a respective linear coil accommodation groove section.

The printed circuit board carrier section 2b may be formed as a plate-shaped projection on the coil carrier body section 2a, which may be smaller than or of the same size as or larger than the printed circuit board 6. If, as shown in FIG. 1, the printed circuit board carrier section 2b is formed to be larger than the printed circuit board 6, the printed circuit board 6 may be inserted into a printed circuit board accommodation groove section 8b formed in the printed circuit board carrier body section 2b. The printed circuit board accommodation groove section 8b may be defined by a web section 2d that at least partially surrounds the printed circuit board accommodation groove section 8b. In illustrative examples and as shown in FIG. 1, the printed circuit board accommodation groove section 8b may be communicatively connected to the coil accommodation groove section 8a, so that the groove 8 is formed by the groove sections 8a and 8b.

One or more mounting portions 9, each having a mounting hole 9a, may be formed on the device body 2, which may project laterally from the coil carrier body section 2a and may be used to mount the sensor device on another object (not shown). The mounting hole 9a may be provided with a reinforcing structure 9b, for example a metal ring inserted into the mounting hole 9a, with optional internal threading.

The design described with reference to FIG. 1 is optimized to minimize the costs for manufacturing the sensor device 10, with the printed circuit board 6 being minimized. To do this, the primary and secondary windings 4a and 4b of the coil structure 4 are designed at least partially as a bendable wire and are each formed by a bendable conductor wire. Accordingly, a footprint area of the printed circuit board 6 in the sensor device may be reduced to a minimum, since the printed circuit board 6 is only necessary for the assembly of discrete components such as an integrated circuit and components necessary for the circuitry.

A method of manufacturing the sensor device 10 may include providing a bendable conductor wire, providing the device body 2, providing one of the primary winding 4a and the at least one secondary winding 4b, wherein at least one of the primary winding 4a and the at least one secondary winding 4b is at least partially formed by the bendable conductor wire on a surface of the device body 2, and providing the circuit board 6 mounted to the device body 2 in connection to at least one of the primary winding 4a and the at least one secondary winding 4b on the device body 2.

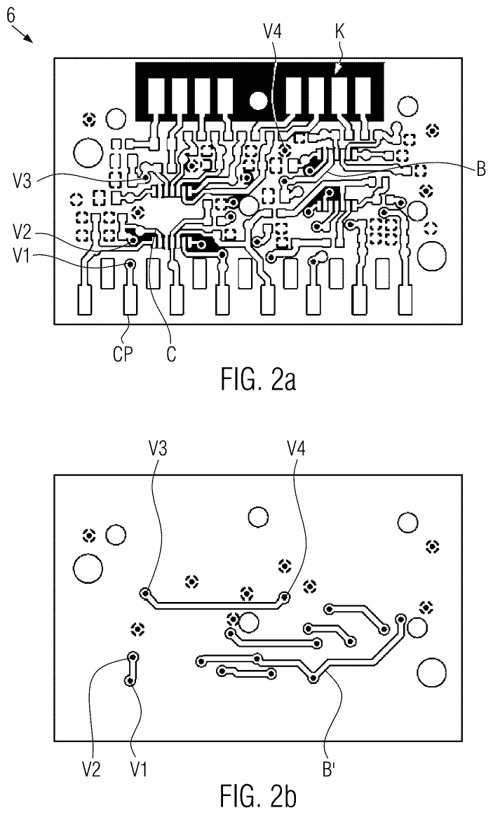

With reference to FIGS. 2a and 2b, two layers of the printed circuit board 6 are shown in plan views. According to FIGS. 2a and 2b, the printed circuit board 6 may only have contacts CP, discrete electrical components such as capacitors K and one or more electrical resistors, and an integrated circuit (such as a chip C). The chip C may comprise at least partially an integrated evaluation and/or drive circuit and may be connected to the primary winding 4a and the secondary windings 4b with contacts CP by means of conductor tracks B.

FIG. 2a may show an upper layer of the printed circuit board 6, wherein vias V1, V2, V3, V4 connect the upper layer to a lower layer shown in FIG. 2b, so that a printed circuit board area of the printed circuit board 6 may be minimized. The vias V1 to V4 may connect conductor tracks B on the upper layer with conductor tracks B′ of the lower layer.

In illustrative examples, the circuit board 6 may have a size of 45×29 mm=1,300 mm², which corresponds to a reduction of approximately 93% in a circuit board used in conventional applications with a size of more than 19,000 mm². In addition, the number of layers of the printed circuit board 6 may be reduced from the previous four layers in conventional printed circuit boards to two layers for the printed circuit board 6, which also results in a price reduction for the printed circuit board 6 compared to conventional printed circuit boards.

In some exemplary embodiments, the sensor device 10 may represent a rotor position sensor of an electrical machine. In this case, a target pattern (not shown) may be attached to an axial surface of a rotor (not shown), for example a rotor of an electrical machine (not shown), the target pattern (not illustrated) optionally being movable with the rotor (not shown). In illustrative examples, the electrical machine (not shown) may be a permanently magnetically excited machine in which an angle signal is used for electrical commutation. Furthermore, the sensor device 10 is provided, which may be arranged axially opposite the target pattern (not shown). The target pattern (not shown) and the sensor device 10 form a sensor system for the rotor position sensor, with the target pattern (not shown) being arranged rotatably relative to the sensor device 10.

According to illustrative examples herein, the target structure (not shown) may be mounted on a suitable substrate (not shown) or directly in a base material of the rotor (not shown), which is seated on a shaft (not shown). A base material of the rotor (not shown) may be understood as representing a material that is intended for the function of the rotor (not shown), such as a material for holding components (not shown) of the electric machine (not shown), such as magnets and the like.

For example, the sensor device 10 comprises a plurality of windings (not shown) and an electronic circuit (not shown) that processes the signals output by the windings and outputs them as position signals, such as electrical signals like voltage amplitudes, differential voltages, current amplitudes, differential currents, frequencies, phase angles, etc. A rotational angle of the rotor (not shown) relative to the sensor device 10 may be derived from these electrical signals output by the electronic circuit (not shown).

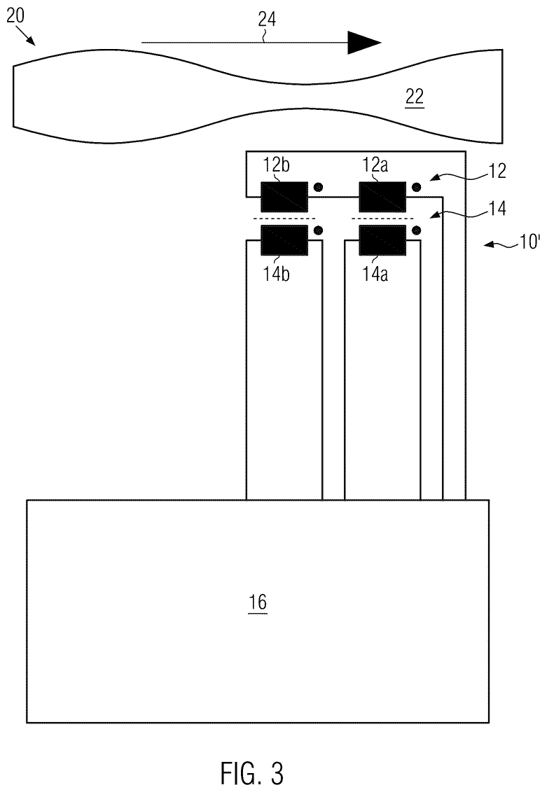

With reference to FIG. 3, a sensor system 20 with a sensor device 10′ and a target element is shown. The target element is illustrated in FIG. 3 by means of a target pattern 22 of the target element. Although the target pattern 22 is shown as a pattern that changes sinusoidally, no limitation is implied and alternative target patterns may be used, such as a rectangular target pattern that is smaller than one period of the coil structure. A direction of movement, for example a direction of rotation for a rotor position sensor, in which the target element moves relative to the sensor device 10′, is shown schematically in FIG. 3 by means of an arrow 24.

The sensor device 10′ may correspond to the sensor device 10 described with reference to FIGS. 1 to 2 above, wherein structural and functional elements described with reference to the sensor device 10 apply to the sensor device 10′ unless otherwise explicitly described below and repetition of redundant description is avoided for conciseness, the description of the sensor device being incorporated in the context of the sensor device 10′ by reference in its entirety.

As shown in FIG. 3, the sensor device 10′ comprises a plurality of primary windings 12 and a plurality of secondary windings 14. These windings are mounted on a device body. The plurality of primary windings 12 may include two primary windings 12a-12b, although this is not a limitation and one primary winding superimposed over the secondary coils or more than two primary windings may be provided instead. The plurality of secondary windings 14 includes two secondary windings 14a and 14b, although this is not a restriction and four or more secondary windings may be provided instead. The number of secondary windings is therefore not limited to two and alternatively a multiple of two or four secondary windings may be provided.

As noted above, the sensor device 10′ may be designed in the same way as the sensor device 10. However, this is not a restriction and, alternatively, the sensor device 10′ may be designed in an alternative way to the sensor device 10, with the sensor device 10′ comprising at least two printed circuit boards (not shown in the schematic representation of FIG. 3) that are electrically connected to one another. In this case, at least one of the primary winding 12 and the secondary windings 14 may be designed as an at least partially integrated wiring, which is at least partially integrated into at least one of the at least two printed circuit boards.

In illustrative examples, the at least two printed circuit boards may further comprise a printed circuit board with only two layers and a printed circuit board with more than two layers. For example, the circuit board with more than two layers may further include at least a portion of an evaluation and drive circuit for one or more of the windings 12, 14 connected thereto and/or at least one of the windings 12, 14 may be completely integrated into the circuit board with only two layers.

Furthermore, the sensor device 10′ may further comprise a device body, such as an injection molded body as described with respect to the sensor device 10 above, except that the at least two printed circuit boards are mounted on the device body, and/or wherein at least one of the primary winding 12 and the secondary windings 14 is formed at most partially by a bendable conductor wire.

A method of manufacturing the sensor device 10′ may comprise providing a bendable conductor wire, providing the device body 2, providing the primary winding 12 and/or the at least one secondary winding 14, wherein at least one of the primary winding 12 and the at least one secondary winding 14 is at least partially formed by the bendable conductor wire on a surface of the device body 2, and providing the circuit board 6 to be attached to the device body 2 in connection to at least one of the primary winding 12 and the at least one secondary winding 14 on the device body 2.

As described above, a number of primary windings in one-to-one correspondence with a number of secondary windings may be provided. Alternatively, a subset of the secondary windings from the plurality of secondary windings may be assigned to exactly one primary winding. For example, a primary winding from a plurality of primary windings may be assigned to two or more secondary windings, so that each primary winding is assigned to a subgroup of secondary windings, with each subgroup having an equal number of secondary windings.

With ongoing reference to FIG. 3, an electronic circuit may be provided by means of the printed circuit board 16. The electronic circuit may apply an electrical signal to the plurality of primary windings 12 and/or may receive electrical signals output by the plurality of secondary windings 14. For example, the electronic circuitry may comprise an oscillator circuit integrated into or coupled to the printed circuit board 16, by means of which a periodic electrical signal may be applied to the plurality of primary windings 12.

For example, the plurality of primary windings 12 may be connected in a resonator circuit that is fed by the oscillator circuit (not shown) integrated into the printed circuit board 16. For example, the plurality of primary windings 12 may be formed by a series connection of the primary windings 12a and 12b. However, no limitation is implied and a suitable parallel connection of the primary windings 12a and 12b may be provided.

The secondary windings 14a and 14b of the plurality of secondary windings 14 may be subdivided into subgroups of two secondary winding groups connected in series (i.e., two secondary windings in each subgroup may be connected in series), each subgroup being separately connected to the printed circuit board 16. For example, the secondary winding 14a may be formed by two or more secondary winding groups connected in series with each other, while the secondary windings 14b may be formed by another subgroup of secondary windings. Each of these subgroups may provide dedicated electrical signals to the printed circuit board 16, on the basis of which an angular position determination may be determined in the sensor system 20. The secondary windings in each subset may be wound and interconnected relative to one another in such a way that a voltage signal output by a subset represents a differential signal at a contact of the printed circuit board 16. This means that a voltage signal output by a subset corresponds to a difference in voltages. For example, the voltage signal output by one subset may be phase shifted with respect to the voltage signal output by another subset, e.g., such that one signal may represent a sinus shaped signal, while the other signal may represent a cosine shaped signal.

In some special but non-limiting examples herein and as described with regard to the embodiments disclosed above on the basis of FIG. 3, all primary windings 12 and all secondary windings 14 may have the same winding orientation relative to each other. The secondary windings 14 may each be connected to one another in subgroups in such a way that differential signals may be picked up by the printed circuit board 16. On the printed circuit board, signals proportional to a sinusoidal signal and a cosinusoidal signal may therefore be provided by the secondary windings, for example, so that an angle signal may be input on the printed circuit board.

With regard to other configurations of the target pattern 22 that differ from the illustrated target pattern 22 (as described above with regard to various configurations of target patterns), a suitable form may be chosen for the secondary windings and primary windings, for example in the form of sinusoidal coils or rectangular coils.

In some illustrative embodiments, the plurality of primary windings 12 may be arranged with respect to the plurality of secondary windings 14 such that one of each of the primary windings 12a and 12b and one of each of the secondary windings 14a and 14b may be arranged in a pair of windings such that these windings in the pair of windings may have maximum inductive coupling as compared to an inductive coupling between a winding of this pair of windings and a winding of another pair of windings. For example, the primary winding 12a and the primary winding 14a may form a pair of windings 12a, 14a having a maximum inductive coupling between the primary winding 12a and the secondary winding 14a when compared to an inductive coupling between the primary winding 12a and the secondary winding 14b and also to an inductive coupling between the secondary winding 14a and the primary winding 12b. Accordingly, the remaining windings 12b and 14b may be arranged in pairs of windings. This may be realized according to a specific illustrative (but not limiting) example in an arrangement of the windings in which a primary winding and a secondary winding are directly opposite each other or interleaved with each other. This arrangement may result in maximum signal strength generated by each pair of windings, so that little to no amplification is required by signals generated by pairs of windings. In further illustrative examples, the primary and secondary windings in a pair of windings may be congruent.

With regard to the above, the windings are described on the basis of primary and secondary windings in the various illustrative embodiments. At least some of these windings may be designed as an air-core coil. This means that no magnetizable core is provided.

With regard to some illustrative embodiments, “sinusoidal” coils are described above. In this context, the term “sinusoidal” is generally understood to mean a shape that repeats itself at least once, where a length of the shape in a maximum length interval in which no repetition of the shape occurs is referred to as a period. In specific illustrative examples, a “cosinusoidal” shape may also be considered to fall under the term “sinusoidal”, since sine and cosine for an angle φ are known to arise from one another through a phase shift of 90° or a quarter of a period: cos φ=sin) (φ+90°).

The term “essentially” is used to express that deviations and modifications are also possible that have little or no influence on the function or the effect to be achieved. Deviations within a range of 50%, for example of at most 25% or of at most 15% or of at most 10% or of at most 5% or of at most 1% are considered tolerable.

With regard to various embodiments of a sensor device with secondary windings connected in a subgroup, the person skilled in the art will appreciate that primary windings and secondary windings may each be coupled and/or connected with a specific winding orientation or sense of winding such that in each of the primary windings associated with a particular subgroup of secondary windings, a magnetic field is generated, which in turn induces a voltage in the respective associated secondary winding of this particular subgroup in such a way that a voltage difference occurs at the connection ends of this particular subgroup to the printed circuit board from the voltages that are correspondingly induced in the individual secondary windings of this particular subgroup. This means that a voltage signal output by a subset corresponds to a difference in voltages. For example, the voltage signal output by one subset may be phase shifted with respect to the voltage signal output by another subset, e.g., such that one signal may represent a sinus shaped signal, while the other signal may represent a cosine shaped signal.

Although applications with regard to a rotor position sensor are described with reference to the figures, this does not represent a limitation. Instead of a rotor position sensor, the invention may be applied to a position sensor that does not directly detect the position of an electric machine rotor but the position of any rotating part, such as a part that is flanged to an electric machine rotor via a gearbox, for example, or a rotating part that only rotates in a limited angular range or continuously, such as any rotating control element.

1. A sensor device for a position sensor, preferably a rotor position sensor, with a printed circuit board, comprising:
a primary winding and at least one secondary winding, wherein at least one of the primary winding and the at least one secondary winding is formed at least partially by a bendable conductor wire; and
a device body, wherein one of the bendable conductor wire of the primary winding and the at least one secondary winding is entirely mounted on a surface portion of the device body.

2. The sensor device according to claim 1, wherein the bendable conductor wire is routed as a planar coil section, preferably with a sinusoidal coil path in the planar coil section.

3. The sensor device according to claim 1, wherein the device body has a groove in which the bendable conductor wire of at least one of the primary winding and the at least one secondary winding is completely routed.

4. The sensor device according to claim 3, wherein the groove has a coil accommodation groove section, formed as a ring-shaped coil groove section in the device body, laterally limited by web sections in the surface of the device body.

5. The sensor device according to claim 3, wherein the groove further comprises a circuit board accommodation groove section configured to completely accommodate a circuit board, wherein the groove is formed on only one surface of the device body.

6. The sensor device according to claim 1, wherein the device body is formed as a plate-shaped or disk-shaped body and the groove is formed in the surface of the device body which is perpendicular to a smallest dimension of the device body.

7. The sensor device according to claim 1, further comprising a printed circuit board mounted to the device body and connected to at least one of the primary winding and the at least one secondary winding on the device body.

8. The sensor device according to claim 7, wherein the printed circuit board covers an area section of the surface portion of the device body of less than 19,000 mm².

9. The sensor device according to claim 7, wherein the printed circuit board comprises less than four layers.

10. The sensor device according to claim 7, wherein the printed circuit board has only contacts, discrete electrical components, preferably at least one capacitor and/or at least one resistor, and an integrated circuit which is connected at least as part of an integrated evaluation and/or drive circuit to at least one of the primary winding and the at least one secondary winding, wherein one or more windings are connected via contacts by conductor tracks to the electrical components.

11. A sensor device for a position sensor, preferably a rotor position sensor, having a printed circuit board, comprising:
a primary winding and at least one secondary winding, wherein at least one of the primary winding and the at least one secondary winding are formed at least in part by a bendable conductor wire;
a device body; and
a printed circuit board mounted to the device body and connected with the bendable conductor wire of at least one of the primary winding and the at least one secondary winding.

12. A sensor device for a position sensor, comprising:
at least two printed circuit boards electrically connected to one another; and
a primary winding and at least one secondary winding, wherein at least one of the primary winding and the at least one secondary winding is at least partially integrated as an at least partially integrated wiring into at least one of the at least two printed circuit boards.

13. The sensor device according to claim 12, wherein the at least two printed circuit boards comprise a printed circuit board having only two layers and a printed circuit board having more than two layers.

14. The sensor device according to claim 13, wherein at least part of an evaluation and drive circuit for one or more of the windings connected thereto is further integrated into the printed circuit board having more than two layers and/or at least one winding is fully integrated into the printed circuit board having only two layers.

15. The sensor device according to claim 12, further comprising a device body, preferably a molded body, on which the at least two printed circuit boards are mounted.

16. The sensor device according to claim 12, wherein at least one of the primary winding and the at least one secondary winding is formed at most partially by a bendable conductor wire.

17. A sensor system comprising:
a sensor device according to claim 1; and
a target element that is rotatably arranged relative to the sensor device,
wherein the target element has a target pattern that is formed of an electrically conductive material.

18. A method of fabricating a sensor device for a position sensor, having a printed circuit board, wherein the method comprises:
providing a bendable conductor wire,
providing a device body,
providing at least one of a primary winding and at least one secondary winding, wherein at least one of the primary winding and the at least one secondary winding are formed at least in part by the bendable conductor wire on a surface of the device body, and
providing a printed circuit board mounted to the device body and connected with at least one of the primary winding and the at least one secondary winding.

19. The sensor device according to claim 7, wherein the printed circuit board covers an area section of the surface portion of the device body of at most 18,500 mm².

20. The sensor device according to claim 7, wherein the printed circuit board covers an area section of the surface portion of the device body of at most 3,000 mm².
